(19) United States
(12) Patent Application Publication
(10) Pub. No.: US 2009/0001514 A1
(43) Pub. Date: Jan. 1, 2009

(54) METAL INSULATOR METAL CAPACITOR AND METHOD OF MANUFACTURING THE SAME

(76) Inventor: Hyun-Su Bae, Icheon-si (KR)

Correspondence Address: SHERR & VAUGHN, PLLC, 620 HERNDON PARKWAY, SUITE 200, HERNDON, VA, 20170, US

(21) Appl. No.: 12/142,074

(22) Filed: Jun. 19, 2008

(30) Foreign Application Priority Data
Jun. 26, 2007 (KR) 10-2007-0062848

(51) Int. Cl. H01L 29/92; H01L 21/02

(52) U.S. Cl. 257/532; 438/393; 257/E29.343; 257/E21.011

(57) ABSTRACT

A metal-insulator-metal (MIM) capacitor may include a lower metal layer including a lower metal layer including a first lower metal layer and a second lower metal layer formed on a semiconductor substrate, an upper metal layer including a first upper metal layer and a second upper metal layer formed on the lower metal layer, a capacitor dielectric layer formed between the lower metal layer and the upper metal layer, a first bonding metal layer formed on the upper metal layer and a second bonding metal layer formed on the lower metal layer, a first connection wiring formed between the upper metal layer and the first bonding metal layer for directly connect the upper metal layer to the first bonding metal layer, and a second connection wiring formed between the lower metal layer and the second bonding metal layer for directly connecting the lower metal layer to the second bonding metal layer.

The present application claims priority under 35 U.S.C. §119 to Korean Patent Application No. 10-2007-0062848 (filed on Jun. 26, 2007), which is hereby incorporated by reference in its entirety.

### BACKGROUND

In the manufacture of a complex chip such that memory components and digital/analog logic components are manufactured simultaneously, it is important to limit the overall number of additional processes and also to take into account characteristics of the respective processes. Currently in progress is an effort for reducing manufacturing costs and improving power consumption via high-speed operation and high-integration of semiconductor devices. As one method of achieving such improvement, a System-On-Chip (SOC) device has been developed in which both a low-voltage device and a high-voltage device are provided in a single chip. In an SOC device, although characteristics of digital devices are important, in particular, characteristics of analog devices such as resistors, inductance coils, and capacitors become important. Therefore, there exists a need for a method of manufacturing a device which can enhance the degree of integration of the device via an improvement in formation of an analog device, more particularly, a capacitor.

As illustrated in example FIG. 1, MIM capacitor 1 may include semiconductor substrate 10, lower metal layer 40 formed on and/or over semiconductor substrate 10, capacitor dielectric layer 50 formed on and/or over a partial region of lower metal layer 40, upper metal layer 60 formed on and/or over capacitor dielectric layer 50, first bonding metal layer 70 formed on and/or over upper metal layer 60, second bonding metal layer 80 formed on and/or over lower metal layer 40 except for the region where capacitor dielectric layer 50 is formed, first contact plug 72 and first connection wiring 74 to connect first bonding metal layer 70 with upper metal layer 60, second contact plug 82 and second connection wiring 84 to connect second bonding metal layer 80 with lower metal layer 40. Lower metal layer 40 and upper metal layer 60 may include, respectively, first metal layers 42 and 62 made of Ti and second metal layers 44 and 64 made of TiN.

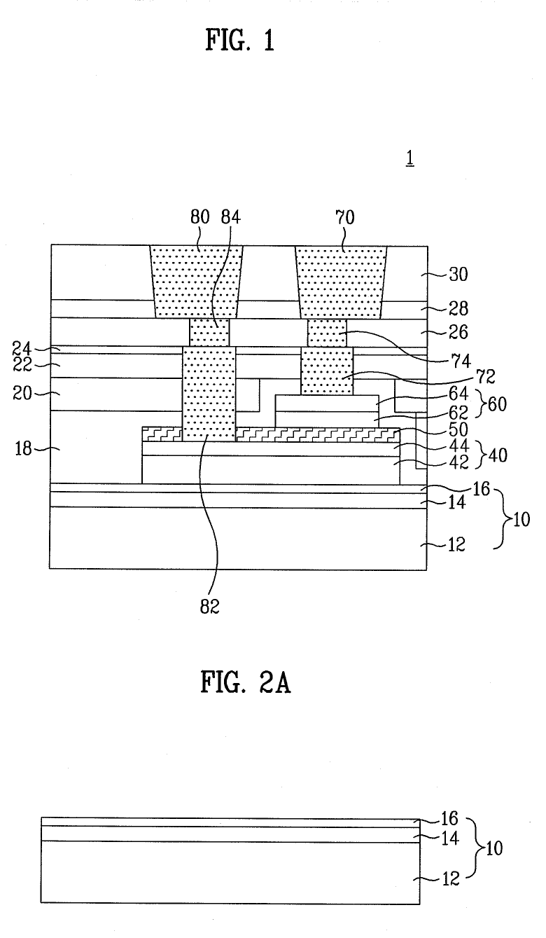

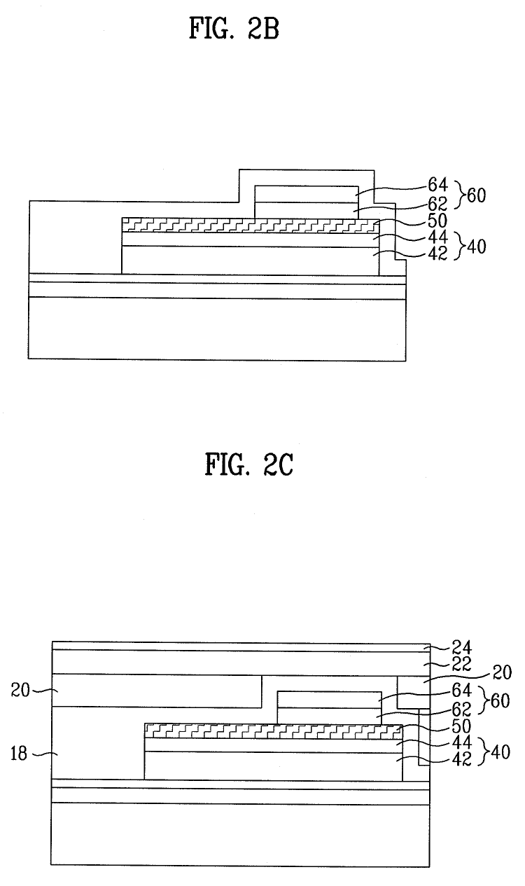

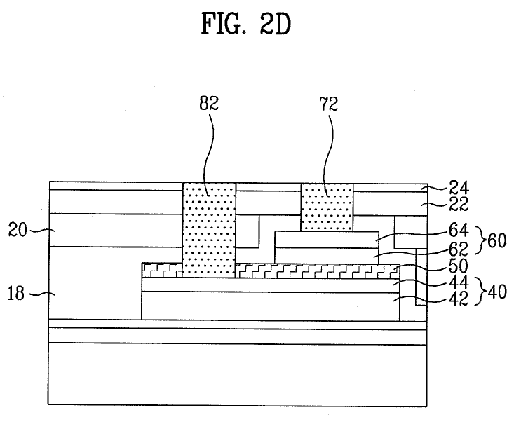

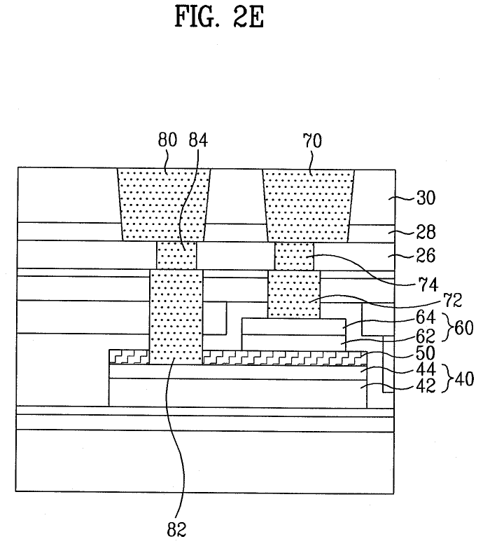

Example FIGS. 2A to 2E illustrate a method of manufacturing the MIM capacitor illustrated in FIG. 1. As illustrated in example FIG. 2A, semiconductor substrate 10, which includes a three layer structure, is prepared. The layers may include FSi layer 12, SiH4 layer 14 and SiN layer 16, which are obtained by oxidation or nitrification of silicon (Si).

As illustrated in example FIG. 2B, Ti layer 42 and TiN layer 44 may then be formed in sequence on and/or over semiconductor substrate 10 including the three silicon oxide or nitride layers 12, 14 and 16, thereby forming lower metal layer 40. Capacitor dielectric layer 50 may then be formed on and/or over the entire surface of lower metal layer 40 to a thickness of 640 Å or more. Ti layer 62 and TiN layer 64 may then be sequentially formed on and/or over a partial region of capacitor dielectric layer 50, thereby forming upper metal layer 60.

As illustrated in example FIG. 2C, silicon oxide (for example, SiH₄ and FSi) layers 18, 20, 22 and 24 may then be formed on and/or over the entire surface of semiconductor substrate 10. The entire surface of semiconductor substrate 10 may then be subjected to photolithography and etching processes using a mask to form photoresist patterns on and/or over lower metal layer 40 and upper metal layer 60.

As illustrated in example FIG. 2D, a metal material such as copper may then be buried in the photoresist patterns formed via the photolithography and etching processes, thereby forming first contact plug 72 on and/or over upper metal layer 60 and second contact plug 82 on and/or over lower metal layer 40. First contact plug 72 and second contact plug 82 may be connected with upper metal layer 60 and lower metal layer 40, respectively. First contact plug 72 may extend through interlayer insulating layer 24, FSi layer 22 and SiN layer 18 to connect with upper metal layer 60. Second contact plug 82 may extend through interlayer insulating layer 24, FSi layer 22, SiH4 layer 20, SiN layer 18 and capacitor dielectric layer 50 to connect with lower metal layer 40. First tetraethly orthosilicate (TEOS) layer 26 may then be formed. The entire surface of first TEOS layer 26 may then be subjected to photolithography and etching processes using a mask whereby photoresist patterns are formed on and/or over first contact plug 72 and second contact plug 82.

As illustrated in example FIG. 2E, a metal material such as copper may then be buried in the patterns formed via the photolithography and etching processes, thereby forming first connection wiring 74 and second connection wiring 84. First connection wiring 74 is connected with first contact plug 72 and second connection wiring 84 is connected with second contact plug 82. Silicon nitride (SiN) layer 28 and second TEOS layer 30 may then be sequentially formed. The entire surface of silicon nitride (SiN) layer 28 and second TEOS layer 30 may then be subjected to photolithography and etching processes using a mask, thereby forming a photoresist pattern on and/or over second TEOS layer 30. A metal material such as copper may then be buried in a resultant via obtained by etching silicon nitride (SiN) layer 28 and second TEOS layer 30 using the photoresist pattern as a mask, thereby forming first bonding metal layer 70 connected with first connection wiring 74 and second bonding metal layer 80 connected with second connection wiring 84.

A problem of the semiconductor device manufactured by the above-described manufacturing process is that, upon formation of the capacitor, contact plugs 72 and 82 and connection wirings 74 and 84 must be provided to connect lower and upper metal layers 40 and 60 of the capacitor with bonding metal layers 70 and 80. This results in a complicated manufacturing process and deteriorated manufacturing efficiency. Furthermore, the resulting semiconductor device may have a reduced degree of integration because of its complicated configuration. This results in an increase in the overall price of the device.

### SUMMARY

Embodiments relate to a metal-insulator-metal (MIM) capacitor and a method of manufacturing the same which can achieve an enhanced manufacturing efficiency via an improvement in manufacturing process, and can result in a reduction in overall price of semiconductor devices by virtue of an enhanced degree of integration.

Embodiments relate to a metal-insulator-metal (MIM) capacitor that can include at least one of the following: a lower metal layer including at least one layer formed on and/or over a semiconductor substrate; an upper metal layer including at least one layer formed on and/or over the lower metal layer; a dielectric layer formed between the lower metal layer and the upper metal layer; a first bonding metal layer formed on and/or over the upper metal layer and a second bonding metal layer formed on and/or over the lower metal layer; a first connection wiring formed between the upper metal layer and the first bonding metal layer to directly connect the upper metal layer with the first bonding metal layer; and a second connection wiring formed between the lower metal layer and the second bonding metal layer to directly connect the lower metal layer with the second bonding metal layer.

Embodiments relate to an apparatus can include at least one of the following: a lower metal layer including a first lower metal layer and a second lower metal layer formed on a semiconductor substrate; an upper metal layer including a first upper metal layer and a second upper metal layer formed on the lower metal layer; a capacitor dielectric layer formed between the lower metal layer and the upper metal layer; a first bonding metal layer formed on the upper metal layer and a second bonding metal layer formed on the lower metal layer; a first connection wiring formed between the upper metal layer and the first bonding metal layer for directly connect the upper metal layer to the first bonding metal layer; and a second connection wiring formed between the lower metal layer and the second bonding metal layer for directly connecting the lower metal layer to the second bonding metal layer.

Embodiments relate to a method of manufacturing a metal-insulator-metal (MIM) capacitor that can include at least one of the following steps: forming a lower metal layer on and/or over a semiconductor substrate; and then forming a capacitor dielectric layer on and/or over the lower metal layer; and then forming an upper metal layer on and/or over a partial region of the dielectric layer; and then forming a first silicon layer to cover the lower metal layer and the upper metal layer; and then forming a second silicon layer on and/or over the semiconductor substrate and the first silicon layer to level surface of the semiconductor substrate; and then forming a first wiring pattern by etching the first and second silicon layers and the dielectric layer to expose a portion of the lower metal layer; and then forming a second wiring pattern by etching the first and second silicon layers to expose a portion of the upper metal layer; and then forming a third silicon layer on and/or over the second silicon layer; and then forming third and fourth wiring patterns by etching the third silicon layer in regions corresponding to the lower metal layer and the upper metal layer; and then simultaneously burying a metal material in the first and second wiring patterns to form connection wirings and a metal material in the third and fourth wiring patterns to form bonding metal layers.

Embodiments relate to a method that can include at least one of the following steps: forming a lower metal layer including a first lower metal layer and a second lower metal layer on a semiconductor substrate; and then forming a capacitor dielectric layer on the lower metal layer; and then forming an upper metal layer first upper metal layer and a second upper metal layer on a portion of the capacitor dielectric layer; and then forming a first silicon layer to cover the lower metal layer and the upper metal layer; and then forming a second silicon layer on the semiconductor substrate including the first silicon layer to level the semiconductor substrate; and then forming a first wiring pattern by etching the first and second silicon layers and the capacitor dielectric layer to expose a portion of the lower metal layer; and then forming a second wiring pattern by etching the first and second silicon layers to expose a portion of the upper metal layer; and then forming a third silicon layer on the second silicon layer; and then forming third and fourth wiring patterns by etching the third silicon layer in regions corresponding to the lower metal layer and the upper metal layer; and then simultaneously burying a metal material in the first and second wiring patterns to form connection wirings and a metal material in the third and fourth wiring patterns to form bonding metal layers.

Embodiments relate to a method that can include at least one of the following steps: sequentially forming a first metal layer on a semiconductor substrate and a second metal layer on the first metal layer; and then forming a first silicon layer on the second metal layer; and then sequentially forming a third metal layer on the capacitor dielectric layer and a fourth metal layer on the third metal layer; and then forming a second silicon layer on the semiconductor substrate including the first metal layer, the second metal layer, the first silicon layer, the third metal layer and the fourth metal layers; and then forming a third silicon layer having a planarized surface on the semiconductor substrate including the second silicon layer; and then performing a first etching process exposing the second metal layer and the fourth metal layer; and then forming a fourth silicon layer on the second silicon layer and the exposed second metal layer and the exposed fourth metal layer; and then performing a second etching process exposing the second metal layer, the fourth metal layer and the third silicon layer; and then simultaneously forming a first connection wiring connected to the fourth metal layer, a fifth metal layer connected to the first connection wiring, a second connection wiring connected to the second metal layer and sixth metal layer connected to the second connection wiring.

### DRAWINGS

Example FIGS. 1 to 2E illustrate an MIM capacitor and a method of manufacturing the MIM capacitor.

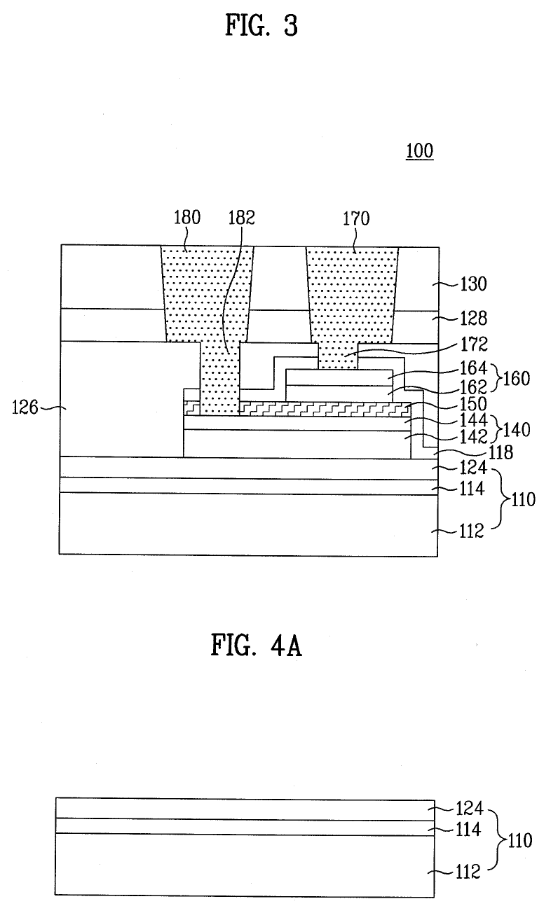

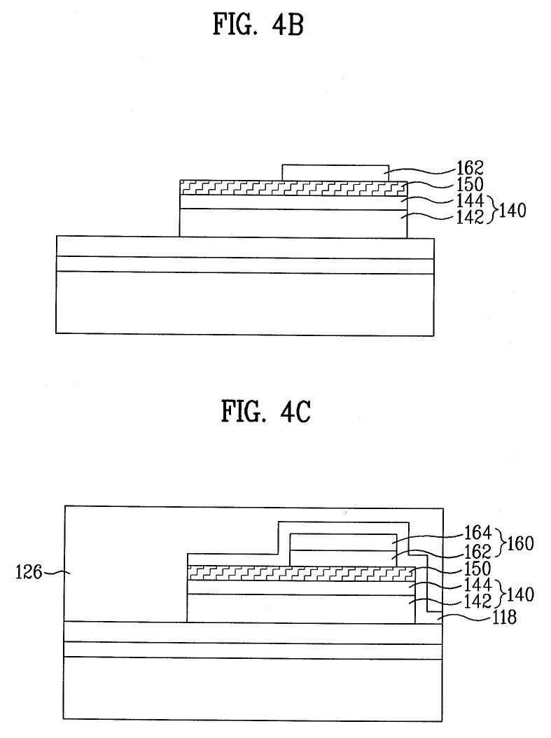

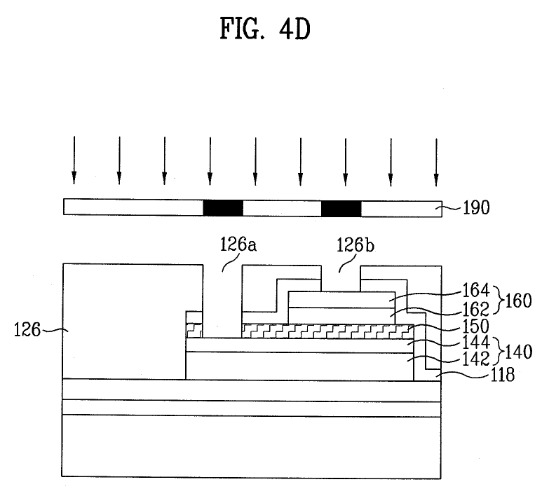

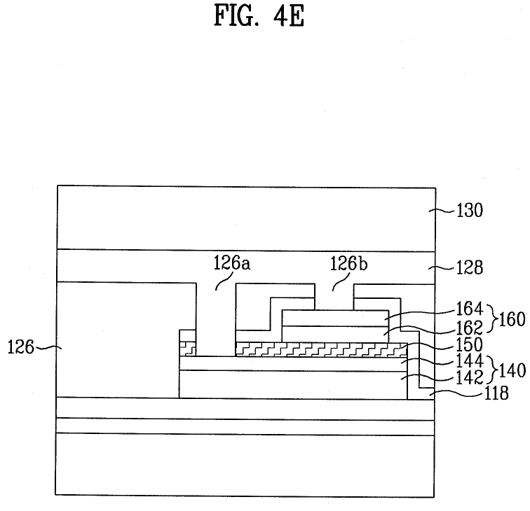

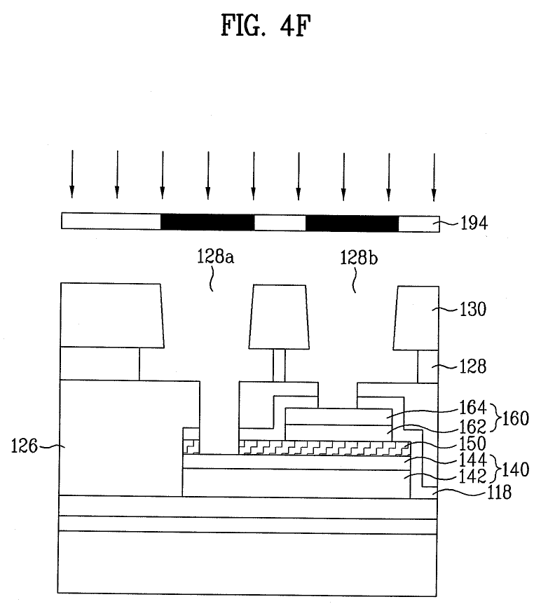

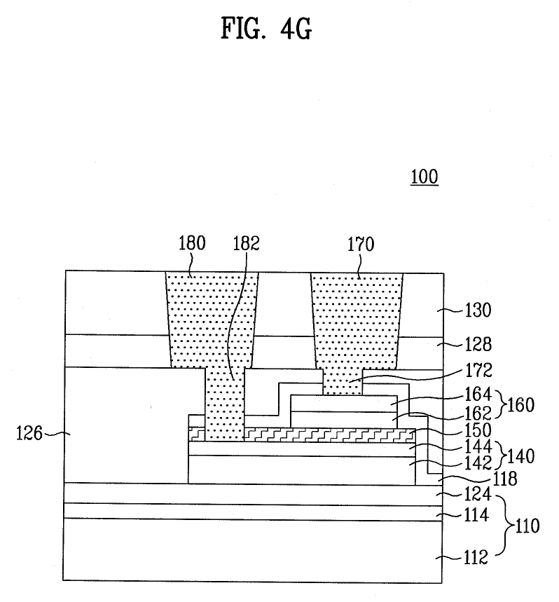

Example FIGS. 3 to 4G illustrate an MIM capacitor and a method of manufacturing an MIM capacitor in accordance with embodiments.

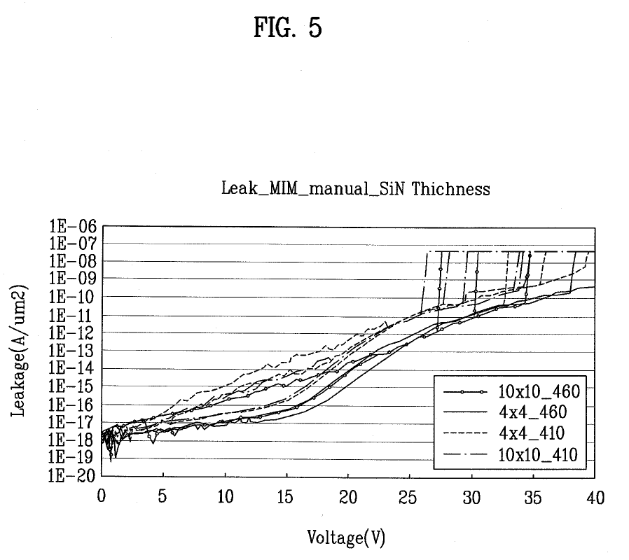

Example FIG. 5 illustrates leakage current characteristics of the MIM capacitor in accordance with embodiments.

### DESCRIPTION

Reference will now be made in detail to the preferred embodiments of the present invention, examples of which are illustrated in the accompanying drawings. Wherever possible, the same reference numbers will be used throughout the drawings to refer to the same or like parts. Hereinafter, an MIM capacitor and a method of manufacturing the same in accordance with embodiments will be described in detail with reference to the accompanying drawings.

As illustrated in example FIG. 3, MIM capacitor 100 in accordance with embodiments may include semiconductor substrate 110, lower metal layer 140 formed on and/or over semiconductor substrate 110. Capacitor dielectric layer 150 may be formed on and/or over lower metal layer 140. Upper metal layer 160 may be formed on and/or over capacitor dielectric layer 150 and first bonding metal layer 170 may be formed on and/or over upper metal layer 160. Second bonding metal layer 180 may be formed on and/or over lower metal layer 140 except for the region where capacitor dielectric layer 150 is formed. First connection wiring 172 may be formed to connect first bonding metal layer 170 to upper metal layer 160. Second connection wiring 182 may be formed to connect second bonding metal layer 180 to lower metal layer 140. Lower metal layer 140 and upper metal layer 160 may be composed of a multi-layered structure include, respectively, first metal layers 142 and 162 composed of Ti and second metal layers 144 and 164 composed of TiN. In MIM capacitor 100, capacitor dielectric layer 150 may be composed of SiN having a reduced thickness in order to obtain enhanced capacitance of MIM capacitor 100. MIM capacitor 100 may be reduced in overall physical size (area) to obtain an enhanced degree of integration of a device. Such characteristics can be understood with reference to the following Equation 1.

$$C = {ɛ}_{o} {ɛ}_{c} \frac{A}{t} \qquad Equation 1$$

In the above Equation 1, “C” represents capacitance of the capacitor, “ε₀” represent a dielectric constant under vacuum conditions, “ε_{c}” represents a dielectric constant of the dielectric layer, “A” represents an area of the dielectric layer, and “t” represents a thickness of the dielectric layer. In an experiment such that thickness t of dielectric layer 150 was varied to 410 Å, 460 Å and 510 Å and area A of capacitor dielectric layer 150 had a fixed value of 2,035 μm², MIM capacitor 100 obtained by the manufacturing method in accordance with embodiments showed experimental results as disclosed in the following example Table 1.

TABLE 1

| | Thickness of | Thickness of Actual | Capacitance |
|---|---|---|---|
| | Theoretical Target | Experimental | Density of |
| | Dielectric Layer | Dielectric Layer | Capacitor |
| | (Å) | (Å) | (fF/μm²) |
| First Dielectric | 410.0 | 412.6 | 1.69 ± 0.01 |
| Layer | | | |
| Second | 460.0 | 456.4 | 1.52 ± 0.01 |
| Dielectric | | | |
| Layer | | | |
| Third | 510.0 | 511.0 | 1.36 ± 0.01 |
| Dielectric | | | |
| Layer | | | |

When designing MIM capacitor 100 to have a capacitance density of 1.5 fF/μm² on the basis of the experimental results of the above Table 1, it can be appreciated that the desired capacitance density of 1.5 fF/μm² of MIM capacitor 100 can be obtained when dielectric layer 150 has an area of 2,035 μm² and a thickness in a range between 450 Å to 460 Å. When the thickness of dielectric layer 150 is set to a value less than 450 Å, it can be appreciated that the area of the capacitor can be reduced to achieve the capacitance density of 1.5 fF/μm² of the capacitor. As can be appreciated from such a reduction in area of the capacitor, integration degree of a device can be increased.

Example FIG. 5 illustrates leakage current characteristics of MIM capacitor 100 manufactured in accordance with embodiments and which has a capacitance density of 1.5 fF/μm². As illustrated in example FIG. 5, the abscissa represents voltage, and the ordinate represents leakage current. MIM capacitor 100 obtained by the manufacturing method in accordance with embodiments showed excellent leakage current characteristics. As can be appreciated from the above experimental results, MIM capacitor 100 can achieve an increased capacitance and an improved degree of integration degree of a device. In addition to the above described advantages and the excellent leakage current characteristics, MIM capacitor 100 can achieve device safety.

As illustrated in example FIG. 4A, a method of manufacturing MIM capacitor 100 in accordance with embodiments can include providing multi-layered semiconductor substrate 110 having first layer 112, second layer 114 and third layer 124. First layer 112 may be composed of FSi, second layer 114 may be composed of SiH and third layer 124 may be composed of SiN which are obtained by oxidation and nitrification of silicon (Si).

As illustrated in example FIG. 4B, lower metal layer 140 including Ti layer 142 and TiN layer 144 may then be sequentially formed on a portion of semiconductor substrate 110 including the three silicon oxide or nitride layers 112, 114 and 124. Ti layer 142 can be formed to a thickness of between 1,200 Å to 1,400 Å and TiN layer 144 can be formed to a thickness of between 400 Å to 600 Å. Capacitor dielectric layer 150 may then be formed on and/or over lower metal layer 140, including TiN layer 144. Capacitor dielectric layer 150 may be composed of a SiN material. In order to achieve a desired capacitance density of 1.5 fF/μm², the thickness of capacitor dielectric layer 150 may be set to a range of between 410 Å to 510 Å, and thus, the area of capacitor dielectric layer 150 can be regulated. Capacitor dielectric layer 150 may also be formed to a thickness of 300 Å to 460 Å. Ti layer 162 may then be formed on and/or over a portion of the uppermost surface of capacitor dielectric layer 150. Ti layer 162 may be formed to a thickness of between 1,200 Å to 1,400 Å.

As illustrated in example FIG. 4C, TiN layer 164 may then be formed on and/or over Ti layer 162, thereby forming upper metal layer 160. TiN layer 164 may be formed to a thickness of between 400 Å to 600 Å. Silicon oxide or silicon nitride layer 118 may then be formed on and/or over upper metal layer 160 and lower metal layer 140 including both sidewalls of upper metal layer 160 and one sidewall of lower metal layer 140. Silicon oxide or silicon nitride layer 118 may be formed to a thickness of between 400 Å to 600 Å. Silicon oxide (SiH₄ or FSi) layer 126 may then be formed on and/or over the entire surface of semiconductor substrate 110 including lower metal layer 140, upper metal layer 160 and silicon oxide or silicon nitride layer 118, thereby leveling surface of the structure formed on and/or over semiconductor substrate 110.

As illustrated in example FIG. 4D, the entire surface of semiconductor substrate 110 is subjected to photolithography and etching processes using mask 190 to form first wiring pattern 126a exposing the a portion of the uppermost surface of lower metal layer 140, e.g., TiN layer 144 and second wiring pattern 126b exposing a portion of the uppermost surface of upper metal layer 160, e.g., TiN layer 164. First wiring pattern 126a formed on and/or over lower metal layer 140 extends through silicon oxide (SiH₄ or FSi) layer 126, silicon oxide or nitride layer 118 and capacitor dielectric layer 150. Second wiring pattern 126b formed on and/or over upper metal layer 160 extends through silicon oxide (SiH₄ or FSi) layer 126 and silicon oxide or nitride layer 118.

As illustrated in example FIG. 4E, silicon nitride (SiN) layer 128 and TEOS layer 130 may then be sequentially formed in sequence filling in first and second wiring patterns 126a and 126b and on and/or over the entire surface of semiconductor substrate 110 including silicon oxide (SiH₄ or FSi) layer 126, lower metal layer 140, upper metal layer 160 and silicon oxide or silicon nitride layer 118.

As illustrated in example FIG. 4F, the entire surface of silicon nitride (SiN) layer 128 and TEOS layer 130 may then be subjected to photolithography and etching processes using mask 194 to form third wiring pattern 128a on and/or over lower metal layer 140 and fourth wiring pattern 128b on and/or over upper metal layer 160.

As illustrated in example FIG. 4G, a metal material such as copper may then be buried in first to fourth wiring patterns 126a, 126b, 128a and 128b formed via the photolithography and etching processes, thereby simultaneously forming first connection wiring 172 connected to upper metal layer 160 and first bonding metal layer 170 connected to first connection wiring 172. In addition, second connection wiring 182 is also simultaneously formed connected to lower metal layer 140 and second bonding metal layer 180 simultaneously formed connected to second connection wiring 182. First connection wiring 172, second connection wiring 182, first bonding metal layer 170 and second bonding metal layer 180 may be simultaneously formed.

As apparent from the above description, the MIM capacitor in accordance with embodiments may have the following effects. Firstly, the MIM capacitor can be manufactured using a reduced number of photolithography and etching processes using a mask, resulting in enhanced device manufacturing efficiency. Secondly, stability in an integration process can be accomplished, and also, a capacitance and integration degree of a device can be enhanced. This has the effect of reducing overall unit cost. Thirdly, as a result of using metal (Ti/TiN) layers connected to metal (copper) wirings as electrode layers of the capacitor, electrical conductivity can be increased, internal parasitic capacitance density of electrodes can be removed, and voltage dependency characteristics can be enhanced.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a lower metal layer including a first lower metal layer and a second lower metal layer formed on a semiconductor substrate;
an upper metal layer including a first upper metal layer and a second upper metal layer formed on the lower metal layer;
a capacitor dielectric layer formed between the lower metal layer and the upper metal layer;
a first bonding metal layer formed on the upper metal layer and a second bonding metal layer formed on the lower metal layer;
a first connection wiring formed between the upper metal layer and the first bonding metal layer for directly connect the upper metal layer to the first bonding metal layer; and
a second connection wiring formed between the lower metal layer and the second bonding metal layer for directly connecting the lower metal layer to the second bonding metal layer.

2. The apparatus of claim 1, wherein the capacitor dielectric layer comprises SiN.

3. The apparatus of claim 1, wherein the capacitor dielectric layer has a thickness in a range between 410 Å to 510 Å.

4. A method comprising:
forming a lower metal layer including a first lower metal layer and a second lower metal layer on a semiconductor substrate; and then
forming a capacitor dielectric layer on the lower metal layer; and then
forming an upper metal layer first upper metal layer and a second upper metal layer on a portion of the capacitor dielectric layer; and then
forming a first silicon layer to cover the lower metal layer and the upper metal layer; and then
forming a second silicon layer on the semiconductor substrate including the first silicon layer to level the semiconductor substrate; and then
forming a first wiring pattern by etching the first and second silicon layers and the capacitor dielectric layer to expose a portion of the lower metal layer; and then
forming a second wiring pattern by etching the first and second silicon layers to expose a portion of the upper metal layer; and then
forming a third silicon layer on the second silicon layer; and then
forming third and fourth wiring patterns by etching the third silicon layer in regions corresponding to the lower metal layer and the upper metal layer; and then
simultaneously burying a metal material in the first and second wiring patterns to form connection wirings and a metal material in the third and fourth wiring patterns to form bonding metal layers.

5. The method of claim 4, further comprising, after forming the third silicon layer, forming a tetraethly orthosilicate (TEOS) layer on the third silicon layer.

6. The method of claim 5, wherein forming the third and fourth wiring patterns comprises etching the third silicon layer and the TEOS layer in regions corresponding to the lower metal layer and the upper metal layer.

7. The method of claim 4, wherein the first lower metal layer comprises Ti and the second lower metal layer comprises TiN.

8. The method of claim 7, wherein the first lower metal layer has a thickness in a range between 1,200 Å to 1,400 Å and the second lower metal layer has a thickness in a range between 400 Å to 600 Å.

9. The method of claim 4, wherein the capacitor dielectric layer comprises SiN and has a thickness in a range between 410 Å to 510 Å.

10. The method of claim 4, wherein the first upper metal layer comprises Ti and the second upper metal layer comprises TiN.

11. The method of claim 10, wherein the first upper metal layer has a thickness in a range between 1,200 Å to 1,400 Å and the second upper metal layer has a thickness in a range between 400 Å to 600 Å.

12. The method of claim 4, wherein the first silicon layer comprises at least one of SiH₄ and SiN and has a thickness in a range between 400 Å to 600 Å.

13. The method of claim 4, wherein the third silicon layer comprises SiN.

14. The method of claim 4, wherein the connection wirings and the bonding metal layers each comprise copper.

15. A method comprising:
sequentially forming a first metal layer on a semiconductor substrate and a second metal layer on the first metal layer; and then
forming a first silicon layer on the second metal layer; and then
sequentially forming a third metal layer on the capacitor dielectric layer and a fourth metal layer on the third metal layer; and then
forming a second silicon layer on the semiconductor substrate including the first metal layer, the second metal layer, the first silicon layer, the third metal layer and the fourth metal layers; and then
forming a third silicon layer having a planarized surface on the semiconductor substrate including the second silicon layer; and then
performing a first etching process exposing the second metal layer and the fourth metal layer; and then
forming a fourth silicon layer on the second silicon layer and the exposed second metal layer and the exposed fourth metal layer; and then
performing a second etching process exposing the second metal layer, the fourth metal layer and the third silicon layer; and then
simultaneously forming a first connection wiring connected to the fourth metal layer, a fifth metal layer connected to the first connection wiring, a second connection wiring connected to the second metal layer and sixth metal layer connected to the second connection wiring.

16. The method of claim 15, wherein the first metal layer and the third metal layer comprise Ti and the second metal layer and the fourth metal layer comprise titanium nitride.

17. The method of claim 15, wherein the first silicon layer comprises SiN, the second silicon layer comprises at least one of SiO₂ and SiN, the third silicon layer comprises at least one of SiH₄ and FSi, and the fourth silicon film comprises SiN.

18. The method of claim 4, wherein the fifth metal layer and the sixth metal layer comprise Cu.

19. The method of claim 4, further comprising, after forming the fourth silicon layer, forming a tetraethly orthosilicate (TEOS) layer on the fourth silicon layer.

20. The method of claim 15, wherein the first silicon layer has a thickness in a range between 410 Å to 510 Å.
